(19) United States
(12) Patent Application Publication
(10) Pub. No.: US 2026/0086151 A1
(43) Pub. Date: Mar. 26, 2026

(54) RAPID PREDICTION METHOD AND SYSTEM FOR COMMUTATION FAILURE IN HVDC BASED ON COMMUTATION FAILURE RISK FACTOR

(71) Applicant: SHANDONG UNIVERSITY, Jinan (CN)

(72) Inventors: Zhijie Liu, Jinan (CN); Kejun Li, Jinan (CN); Miao Guo, Jinan (CN); Zhonglin Guo, Jinan (CN); Baihe Su, Jinan (CN); Canyu Cui, Jinan (CN); Yuanyuan Sun, Jinan (CN); Kaiqi Sun, Jinan (CN); Shuang Li, Jinan (CN)

(73) Assignee: SHANDONG UNIVERSITY, Jinan (CN)

(21) Appl. No.: 19/404,149

(22) Filed: Dec. 1, 2025

(30) Foreign Application Priority Data
Apr. 30, 2025 (CN) 2025105624141

(51) Int. Cl. G01R 31/327; H02J 3/36

(52) U.S. Cl. CPC G01R 31/3275; H02J 3/36

(57) ABSTRACT

Disclosed are a rapid prediction method and system for a commutation failure in a high voltage direct current transmission system (HVDC) based on a commutation failure risk factor, belonging to the technical field of commutation failure prevention in the high voltage direct current transmission system. The method can rapidly predict whether the commutation failure occurs after a fault occurs in a line-commutated converter-HVDC (LCC-HVDC) system, thereby supporting the subsequent prevention of the commutation failure. During the implementation, the method defines a conventional commutation area and an advanced commutation area, and calculates a commutation failure risk factor by integrating the conventional commutation area and the advanced commutation area, thereby predicting the commutation failure. In the method, the present-instant information and the future-instant information of characteristic quantities are comprehensively considered during a prediction process, thereby improving the commutation failure prediction speed.

### CROSS-REFERENCE TO RELATED APPLICATIONS

This application claims priority to Chinese Patent Application Ser. No. CN2025105624141 filed on 30 Apr. 2025.

### FIELD OF THE INVENTION

The present disclosure relates to a rapid prediction method and system for a commutation failure in a high voltage direct current transmission system (HVDC) based on a commutation failure risk factor, belonging to the technical field of commutation failure prevention in the HVDC.

### BACKGROUND OF THE INVENTION

Line-commutated converter-HVDC (LCC-HVDC) technologies have advantages of large transmission capacity, low losses, and low cost. It can effectively resolve the problem of uneven distribution between energy centers and load centers and ensure a reliable and stable power supply. Commutation failure (CF), one of the most common faults of LCC-HVDC, occurs in a commutation process, manifesting as the failure of thyristors to turn off or turn on properly, thereby threatening the stability and reliability of the power supply in electric systems. Upon occurrence of the commutation failure, abnormal fluctuations will occur in AC/DC systems, imposing both active and reactive power shocks on LCC-HVDC systems, and threatening the stability and reliability of the entire power system. Consecutive commutation failures may even trigger severe faults or widespread blackouts. Consequently, commutation failure prevention technologies have become a research hotspot, and commutation failure prediction is a key link, which is a critical basis for the activation of a commutation failure control and protection system. If the commutation failure can be predicted in advance, an operation state of the system can be adjusted to increase a commutation margin before the actual commutation failure occurs, thus avoiding the occurrence of the commutation failure and improving the safety and stability of the system operation. In conclusion, rapidly and accurately predicting commutation failure is of critical importance for the safe and stable operation of the power system.

For the above problems, the existing mostly analyzes the commutation process of converters based on a theory of commutation voltage-time integral area, and predicts the commutation failure by comparing a defined required commutation area with an available commutation area.

However, conventional commutation failure prediction methods based on a commutation area theory predict commutation failures at a future instant using characteristic quantities measured at a present instant. During the prediction process, these methods ignore transient changes in characteristic quantities such as commutation voltage and direct current from the present measurement instant to the future instant. This results in a limit to the advanced prediction time for commutation failure in this method, namely, half a power frequency cycle. Therefore, the conventional prediction methods are low in prediction speed when predicting the commutation failure, and susceptible to missed prediction. This problem has become a critical issue that limits the prediction accuracy of the commutation failure in the field of HVDC commutation failure prevention.

### SUMMARY OF THE INVENTION

In view of deficiencies in the prior art, and to resolve the technical problems in the above background art, the present disclosure provides a rapid prediction method for a commutation failure in a high voltage direct current transmission system (HVDC) based on a commutation failure risk factor, which can predict the commutation failure more rapidly after a fault occurs in a line-commutated converter-HVDC (LCC-HVDC) system.

The present disclosure adopts a technical solution as follows:

A rapid prediction method for a commutation failure in an HVDC based on a commutation failure risk factor includes the following steps:
step 1: obtaining, in real-time, a present-instant commutation voltage magnitude U_{com.t}, a present-instant DC current I_{d.t}, a future-instant commutation voltage magnitude U_{com.c}, a future-instant DC current I_{d.c}, and a firing angle instruction value a during the operation of an LCC-HVDC system, where all values are per-unit values;
step 2: calculating a required commutation area and an available maximum commutation area based on the present-instant commutation voltage magnitude U_{com.t}, the present-instant DC current I_{d.t}, and the firing angle instruction value a, and defining the calculated required commutation area and the calculated available maximum commutation area as a conventional required commutation area and a conventional available maximum commutation area respectively. and simultaneously, to enhance a prediction speed for the commutation failure and overcome the limitation in prediction time of the conventional prediction methods, calculating a required commutation area and an available maximum commutation area based on the predicted future-instant commutation voltage magnitude U_{com.c}, the future-instant DC current I_{d.c}, and the firing angle instruction value a, and defining the calculated required commutation area and the calculated available maximum commutation area as an advanced required commutation area and an advanced available maximum commutation area respectively;
preferably, in step 2, based on the present-instant commutation voltage magnitude U_{com.t}, the present-instant DC current I_{d.t}, and the firing angle instruction value a, calculating a conventional required commutation area S_{need.t} and a conventional available maximum commutation area S_{pro.t} according to Formula (2) and Formula (3), respectively;
based on the predicted future-instant commutation voltage magnitude U_{com.c}, the future-instant DC current I_{d.c}, and the firing angle instruction value a, calculating the advanced required commutation area S_{need.c} and the advanced available maximum commutation area S_{pro.c} according to Formula (4) and Formula (5), respectively;

$${S}_{n eed . t} = 2 {X}_{c} {I}_{d . t} \qquad ( 2 )$$

$${S}_{pro . t} = {\int }_{α}^{π - {γ}_{min}} {U}_{com . t} sin ( {ω}_{0} t ) d ( {ω}_{0} t ) \qquad ( 3 )$$

$${S}_{need . c} = 2 {X}_{c} {I}_{d . c} \qquad ( 4 )$$

$${S}_{pro . c} = {\int }_{α}^{π - {γ}_{min}} {U}_{com . c} sin ( {ω}_{0} t ) d ( {ω}_{0} t ) \qquad ( 5 )$$

where X_{c} denotes the equivalent commutation reactance; γₘᵢₙ denotes a minimum extinction angle; ω₀ denotes a system angular frequency, with a value of 2π/T, where T is a fundamental period of the system; and t denotes an integral variable.
step 3: in consideration of the fact that the calculated future-instant commutation voltage magnitude U_{com.c} and the future-instant DC current I_{d.c} may potentially have errors in certain scenarios, calculating weight coefficients of the conventional required commutation area and the advanced required commutation area;
preferably, in step 3, based on the present-instant DC current I_{d.t} and a predicted value I_{d.c0} of the present DC current in historical data, calculating weight coefficients C₁ and C₂ of the conventional required commutation area and the advanced required commutation area according to Formula (6);

$$\{ \begin{matrix}{C}_{1} = - \frac{{k}_{i 1} {e}^{{k}_{i 2} \vert {I}_{d . t} {I}_{d . c 0} \vert}}{1 + {e}^{{k}_{i 2} \vert {I}_{d . t} - {I}_{d . c 0} \vert}} \\ {C}_{2} = - 1 - {C}_{1}\end{matrix} ; \qquad ( 6 )$$

and
where kᵢ₁ denotes a normalization coefficient of required commutation area weights, and kᵢ₂ denotes a sensitivity coefficient of the required commutation area weights.
step 4: calculating weight coefficients of the conventional available maximum commutation area and the advanced available maximum commutation area;
preferably, in step 4, based on the present-instant commutation voltage magnitude U_{com.t} and a predicted value U_{com.c0} of the present commutation voltage magnitude in the historical data, calculating weight coefficients C₃ and C₄ of the conventional available maximum commutation area and the advanced available maximum commutation area according to Formula (7);

$$\{ \begin{matrix}{C}_{3} = \frac{{k}_{u 1} {e}^{{k}_{u 2} \vert {U}_{com . t} - {U}_{com . c 0} \vert}}{1 + {e}^{{k}_{u 2} \vert {U}_{com . t} - {U}_{com . c 0} \vert}} \\ {C}_{4} = 1 - {C}_{3}\end{matrix} \qquad ( 7 )$$

where kᵤ₁ denotes a normalization coefficient of available maximum commutation area weights, and kᵤ₂ denotes a sensitivity coefficient of the available maximum commutation area weights.
step 5: performing weighted integration on the calculated conventional required commutation area, the calculated conventional available maximum commutation area, the calculated advanced required commutation area, and the calculated advanced available maximum commutation area through the weight coefficients, to obtain a commutation failure risk factor, and then predicting whether a commutation failure will occur; and during a prediction process, adaptively adjusting the weight coefficients of the commutation areas according to prediction errors of characteristic quantities at a previous instant, where the prediction errors of the characteristic quantities are absolute values in Formula (6) and Formula (7), a prediction error of the DC current is |I_{d.t}−I_{d.c0}|, a prediction error of the commutation voltage is |U_{com.t}−U_{com.c0}|, the adjustment of the weight coefficients is as shown in Formula (6) and Formula (7), the prediction errors of the characteristic quantities change in real time as an operation state of the system changes, the weight coefficient of each commutation area is adjusted adaptively with the real-time prediction error of the feature (a real-time calculation process according to Formula (6) and Formula (7) is the adaptive adjustment). If the prediction error of the commutation voltage is large, the weight coefficient of the advanced available maximum commutation area is relatively small, while the weight coefficient of the conventional available maximum commutation area is relatively large. DC current is the same. On the premise of ensuring the prediction accuracy, the prediction speed for the commutation failure is improved.

Preferably, in step 5, based on the conventional required commutation area S_{need.t}, the conventional available maximum commutation area S_{pro.t}, the advanced required commutation area S_{need.c}, the advanced available maximum commutation area S_{pro.c}, and the weight coefficients C₁ to C₄ calculated in step 2 to step 4, calculating the commutation failure risk factor F in real time according to Formula (8);

$$F = {C}_{1} {S}_{n e e d . c} + {C}_{2} {S}_{n eed . t} + {C}_{3} {S}_{pro . c} + {C}_{4} {S}_{pro . t} \qquad ( 8 )$$

where if F≥0, a system state satisfies a normal commutation condition, and the commutation failure will not occur; and if F<0, the system state does not satisfy the normal commutation condition, and the commutation failure will occur.

After the prediction for the commutation failure is completed, the system may perform adjustment according to a prediction result. If the prediction indicates that the commutation failure will not occur, the present operation state and control parameters of the system may remain unchanged, to avoid system fluctuation; and if the prediction shows that the commutation failure will occur, measures may be taken, such as appropriately decreasing a firing angle instruction, and/or activating an external energy storage device to increase the AC voltage, thereby augmenting the commutation margin and preventing the occurrence of the commutation failure.

Provided is a computer readable storage medium having programs stored thereon, the programs, when executed by a processor, performing the steps in the rapid prediction method for the commutation failure in the HVDC based on the commutation failure risk factor.

Provided is an electronic device, including a memory, a processor, and programs stored in the memory and capable of running on the processor, the processor, when executing the programs, performing the steps in the rapid prediction method for the commutation failure in the HVDC based on the commutation failure risk factor.

### The Present Disclosure has the Beneficial Effects:

The present disclosure provides the rapid prediction method for the commutation failure in the HVDC based on the commutation failure risk factor, which essentially achieves early prediction of a first commutation failure, to facilitate the subsequent prevention of the commutation failure. The method can rapidly and accurately predict whether the commutation failure occurs after a fault occurs in the LCC-HVDC system, thereby supporting the subsequent prevention of the commutation failure. During the implementation, the method defines the conventional commutation area and the advanced commutation area, and predicts the commutation failure by integrating the conventional commutation area and the advanced commutation area. In the method, the present-instant information and the future-instant information of the characteristic quantities are comprehensively considered during a prediction process, to ensure the rapidity and accuracy of the prediction, and improve the commutation failure prediction speed. At the same time, the weight coefficients of the conventional commutation area and advanced commutation area can be adaptively adjusted according to the prediction errors of the characteristic quantities, and the commutation failure risk factor is defined to predict the commutation failure, so that the reduction in the commutation failure prediction accuracy caused by large prediction errors of the characteristic quantities can be avoided, and the reliability of the prediction result can be ensured.

### BRIEF DESCRIPTION OF THE DRAWINGS

FIG. 1 is a structural diagram of a 6-pulse converter;

FIG. 2 is a flowchart of a prediction method for a commutation failure based on a commutation failure risk factor according to the present disclosure;

FIG. 3 is a main structural diagram of an LCC-HVDC system;

FIG. 4a shows waveforms of direct current, three-phase AC bus voltage, and valve current under a single-phase ground fault occurring at 0.17 H, where shows the DC current waveform in proximity to the fault instant;

FIG. 4b shows waveforms of direct current, three-phase AC bus voltage, and valve current under a single-phase ground fault occurring at 0.17 H, where shows the three-phase AC bus voltage waveform of an inverter station in proximity to the fault instant;

FIG. 4c shows waveforms of direct current, three-phase AC bus voltage, and valve current under a single-phase ground fault occurring at 0.17 H, where shows the valve current waveform of two valves where a first commutation failure occurs;

FIG. 5a shows waveforms of direct current, three-phase AC bus voltage, and valve current under a three-phase symmetrical ground fault occurring at 0.18 H, where shows the DC current waveform in proximity to the fault instant;

FIG. 5b shows waveforms of direct current, three-phase AC bus voltage, and valve current under a three-phase symmetrical ground fault occurring at 0.18 H, where shows the three-phase AC bus voltage waveform of an inverter station in proximity to the fault instant;

FIG. 5c shows waveforms of direct current, three-phase AC bus voltage, and valve current under a three-phase symmetrical ground fault occurring at 0.18 H, where shows the valve current waveform of two valves where a first commutation failure occurs.

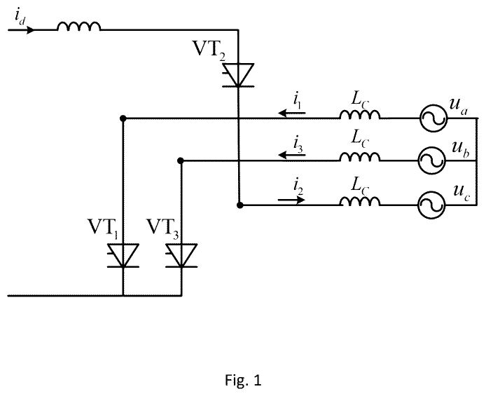

### DETAILED DESCRIPTION OF THE EMBODIMENTS

To make technical solutions of the present disclosure more clear and understandable, a rapid prediction process for a commutation failure in the present disclosure is described in detail below in combination with accompanying drawings and embodiments, but the present disclosure is not limited thereto.

### Embodiment 1

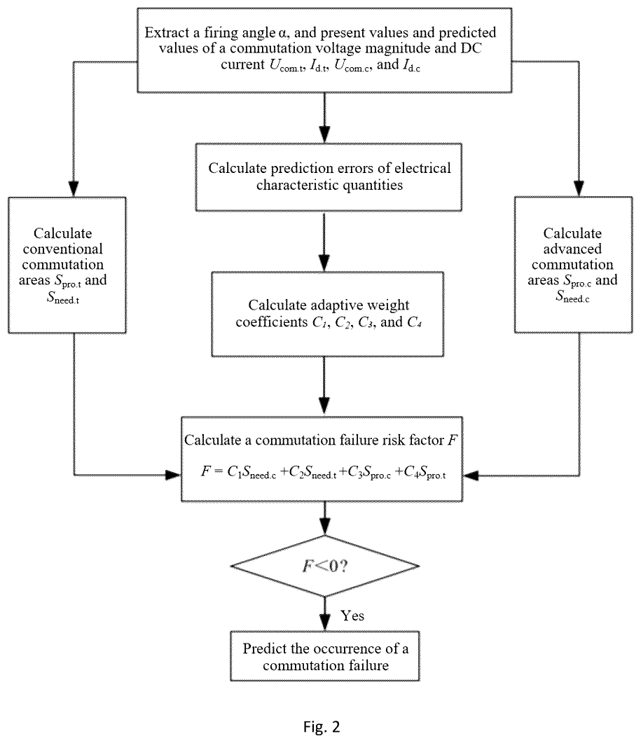

A process of a rapid prediction method for a commutation failure in a high voltage direct current transmission system (HVDC) based on a commutation failure risk factor is as shown in FIG. 2. Steps are as follows:
Step 1: acquire, in real-time, and calculate a present-instant commutation voltage magnitude U_{com.t}, a present-instant DC current I_{d.t}, a future-instant commutation voltage magnitude U_{com.c}, a future-instant DC current I_{d.c}, and a firing angle instruction value α (all are per-unit values) of a converter station during an operation process of aline-commutated converter-HVDC (LCC-HVDC) system.

The present-instant DC current I_{d.t} and the firing angle instruction value a are acquired in real time, and the present-instant commutation voltage magnitude U_{com.t} cannot be acquired directly, and is calculated by using a real-time acquired instantaneous value of the commutation voltage through a conventional known algorithm. The future-instant commutation voltage magnitude U_{com.c} and the future-instant DC current I_{d.c} are calculated by using a conventional prediction algorithm based on the present-instant commutation voltage magnitude U_{com.t} and the future-instant DC current I_{d.t}. An actual prediction method may be selected freely as long as the predicted value including the future-instant information can be calculated.

In the present embodiment, the method of calculating the future-instant DC current I_{d.c} by using the present-instant DC current I_{d.t} employs a fundamental principle of a Taylor expansion, as shown in the following formula. In the formula, t₀ denotes a present instant, t_{c} denotes a prediction future instant,

$$\frac{d {I}_{d} ( {t}_{0} )}{d t}$$

denotes an approximate first-order differential of the present-instant DC current, and

$$\frac{{d}^{2} {I}_{d} ( {t}_{0} )}{{dt}^{2}}$$

denotes an approximate second-order differential of the present-instant DC current. In the present disclosure, T₁ is set to 1 ms, and T₂ is set to 8 ms.

$$\{ \begin{matrix}{I}_{d . c} ( {t}_{0} ) = {I}_{d . t} ( {t}_{0} ) + \frac{d {I}_{d} ( {t}_{0} )}{d t} ( {t}_{c} - {t}_{0} ) + \frac{{d}^{2} {I}_{d} ( {t}_{0} )}{d {t}^{2}} \frac{{( {t}_{c} - {t}_{0} )}^{2}}{2} \\ \frac{d {I}_{d} ( {t}_{0} )}{d t} = \frac{{I}_{d . t} ( {t}_{0} ) - {I}_{d . t} ( {t}_{0} - {T}_{1} )}{{T}_{1}} \\ \frac{{d}^{2} {I}_{d} ( {t}_{0} )}{{dt}^{2}} = \frac{1}{{T}_{2}} [ \frac{{dI}_{d} ( {t}_{0} )}{dt} - \frac{{dI}_{d} ( {t}_{0} - {T}_{2} )}{dt} ]\end{matrix} \qquad ( 1 )$$

The values of the aforementioned characteristic quantities may be obtained by conventional known methods and are treated as known values in step 1.
Step 2: based on the present-instant commutation voltage magnitude U_{com.t}, the present-instant DC current I_{d.t}, and the firing angle instruction value α, calculate a conventional required commutation area S_{need.t} and a conventional available maximum commutation area S_{pro.t} according to Formula (2) and Formula (3), respectively. Based on the predicted future-instant commutation voltage magnitude U_{com.c}, the future-instant DC current I_{d.c}, and the firing angle instruction value α, calculate an advanced required commutation area S_{need.c} and an advanced available maximum commutation area S_{pro.c} according to Formula (4) and Formula (5), respectively.

$${S}_{n eed . t} = 2 {X}_{c} {I}_{d . t} \qquad ( 2 )$$

$${S}_{pro . t} = {\int }_{α}^{π - {γ}_{min}} {U}_{com . t} sin ( {ω}_{0} t ) d ( {ω}_{0} t ) \qquad ( 3 )$$

$${S}_{need . c} = 2 {X}_{c} {I}_{d . c} \qquad ( 4 )$$

$${S}_{pro . c} = {\int }_{α}^{π - {γ}_{min}} {U}_{com . c} sin ( {ω}_{0} t ) d ( {ω}_{0} t ) \qquad ( 5 )$$

where X_{c} denotes the equivalent commutation reactance; γₘᵢₙ denotes a minimum extinction angle; ω₀ denotes a system angular frequency, with a value of 2π/T, where T is a fundamental period of the system; and t denotes an integral variable.
Step 3: based on the present-instant DC current I_{d.t} and a predicted value I_{d.c0} of the present DC current in historical data, calculate weight coefficients C₁ and C₂ of the conventional required commutation area and the advanced required commutation area according to Formula (6).

$$\{ \begin{matrix}{C}_{1} = - \frac{{k}_{i 1} {e}^{{k}_{i 2} \vert {I}_{d . t} {I}_{d . c 0} \vert}}{1 + {e}^{{k}_{i 2} \vert {I}_{d . t} - {I}_{d . c 0} \vert}} \\ {C}_{2} = - 1 - {C}_{1}\end{matrix} \qquad ( 6 )$$

where kᵢ₁ denotes a normalization coefficient of required commutation area weights, and kᵢ₂ denotes a sensitivity coefficient of the required commutation area weights.
Step 4: based on the present-instant commutation voltage magnitude U_{com.t} and a predicted value U_{com.c0} of the present commutation voltage magnitude in the historical data, calculate the weight coefficients C₃ and C₄ of the conventional available maximum commutation area and the advanced available maximum commutation area according to Formula (7).

$$\{ \begin{matrix}{C}_{3} = \frac{{k}_{u 1} {e}^{{k}_{u 2} \vert {U}_{com . t} - {U}_{com . c 0} \vert}}{1 + {e}^{{k}_{u 2} \vert {U}_{com . t} - {U}_{com . c 0} \vert}} \\ {C}_{4} = 1 - {C}_{3}\end{matrix} \qquad ( 7 )$$

where kᵤ₁ denotes a normalization coefficient of available maximum commutation area weights, and kᵤ₂ denotes a sensitivity coefficient of the available maximum commutation area weights.
Step 5: based on the conventional required commutation area S_{need.t}, the conventional available maximum commutation area S_{pro.t}, the advanced required commutation area S_{need.c}, the advanced available maximum commutation area S_{pro.c}, and the weight coefficients C₁ to C₄ calculated in step 2 to step 4, calculate the commutation failure risk factor F in real time according to Formula (8);

$$F = {C}_{1} {S}_{n e e d . c} + {C}_{2} {S}_{n eed . t} + {C}_{3} {S}_{pro . c} + {C}_{4} {S}_{pro . t} \qquad ( 8 )$$

where if F≥0, a system state satisfies a normal commutation condition, and the commutation failure will not occur; and if F<0, the system state does not satisfy the normal commutation condition, and the commutation failure will occur.

### Experimental Example

The feasibility of the rapid prediction method for the commutation failure disclosed in the present disclosure is validated below by using the method of Embodiment 1 in conjunction with parameters of LCC-HVDC listed in Table 1.

TABLE 1
LCC-HVDC Parameter

| | Numerical | |
|---|---|---|
| Parameter | value | |
| Rectifier-side rated | 500 | kV |
| voltage U_{rec} | | |
| Rectifier-side rated | 50 | Hz |
| frequency f_{rec} | | |
| Inverter-side rated | 345 | kV |
| voltage Uᵢₙᵥ | | |
| Inverter-side rated | 50 | Hz |
| frequency fᵢₙᵥ | | |
| DC-side rated | 500 | kV |
| voltage U_{d} | | |
| DC-side rated | 2000 | A |
| current I_{d} | | |
| Inverter AC-side | 28 | mH |
| inductance Lₜ | | |
| Equivalent | 0.02546 | H |

commutation
inductance L_{c}

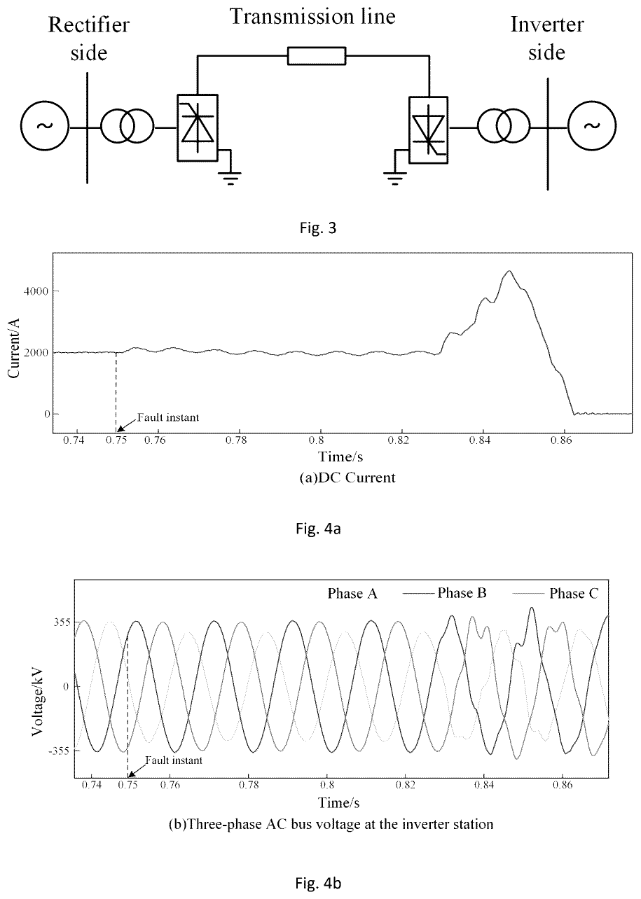

The validation is carried out in a monopolar LCC-HVDC standard model shown in FIG. 3, where converter stations on both a rectifier side and an inverter side employ 12-pulse converters (each is formed by two 6-pulse converters in serial connection); and a three-phase three-winding converter transformer is used, where the high-voltage side is connected in a Yg configuration, and the two low-voltage windings are connected in a Y configuration and a D1 configuration respectively and supply commutation voltage to the two 6-pulse converters. The LCC-HVDC parameters are as shown in table 1. In the present example, a ground fault was applied at an inverter-side AC bus at 0.75 s during the normal operation of the LCC-HVDC, and the system commutation failure was then predicted by using both the conventional commutation failure prediction method and the method disclosed in the present disclosure. The method disclosed in the present disclosure was validated by comparing prediction effects of the two methods.

The rapidity of the disclosed method is validated below by comparing prediction effects of the rapid prediction method for the commutation failure disclosed in the present disclosure and the existing prediction method based on a commutation area. Relevant parameters are set as follows: a normalization coefficient kᵢ₁ of required commutation area weights is 1.7, a sensitivity coefficient kᵢ₂ of the required commutation area weights is −20, a normalization coefficient kᵤ₁ of available maximum commutation area weights is 1.8, and a sensitivity coefficient kᵤ₂ of the available maximum commutation area weights is −60. As can be seen from Formula (6), kᵢ₁ plays a role in limiting the calculated weight coefficients C₁ and C₂ in a range of [−0.9, 0] to prevent the excessively large or small value of C₁ and C₂; kᵢ₂ describes a sensitivity degree of the weight coefficients C₁ and C₂ to a change of a DC current prediction error. The greater the absolute value of kᵢ₂, the more sensitive the weight coefficients C₁ and C₂ are to changes in the DC current prediction error. Similarly, as can be seen from Formula (7), kᵤ₁ plays a role in limiting the calculated weight coefficients C₃ and C₄ in a range of [0, 0.9], and kᵤ₂ describes a sensitivity degree of the weight coefficients C₃ and C₄ to a change of a commutation voltage magnitude prediction error. The greater the absolute value of kᵤ₂, the more sensitive the weight coefficients C₃ and C₄ are to changes in the commutation voltage magnitude prediction error. In the disclosed prediction method, the parameters such as kᵢ₁, kᵢ₂, kᵤ₁, and kᵤ₂ directly influence the rapidity and accuracy of the prediction method. Therefore, these parameters need to be properly set before the prediction.

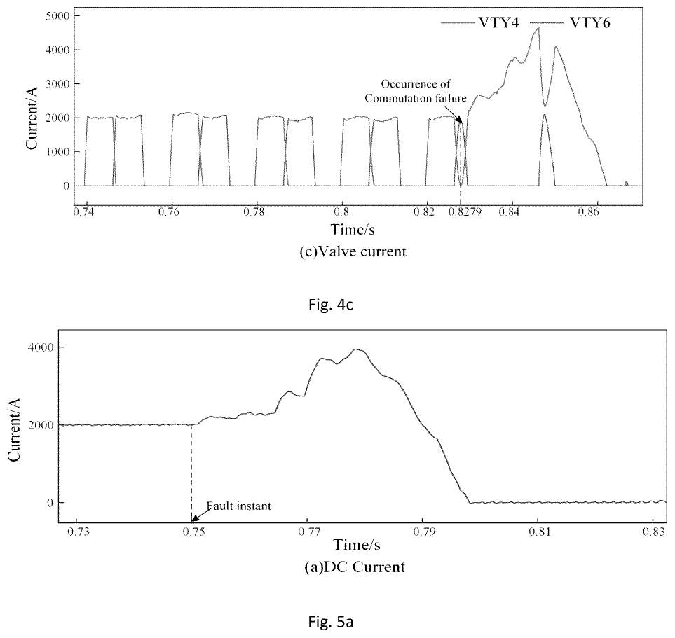

Since the commutation failure during the operation of the LCC-HVDC is usually caused by the single-phase ground fault, the method is validated first by taking the single-phase ground fault as an example. A phase-A ground fault was set at an inverter-side AC bus of the LCC-HVDC system, a ground impedance was 0.17H. Relevant waveforms under the condition are shown in FIG. 4; and in FIG. 4, (a) shows a DC current waveform in proximity to a fault instant; (b) shows a three-phase AC bus voltage waveform in proximity to the fault instant; and (c) shows a valve current waveform of two valves where a first commutation failure occurs. As can be seen from FIG. 4, upon the occurrence of the single-phase ground fault, the DC current exhibits fluctuations and the AC voltage of a faulted phase shows a significant drop; and furthermore, the first commutation failure occurs at 0.8279 s during the commutation process of valves 4 to 6 of a converter corresponding to the Y-connected transformer. After the commutation failure occurs, the DC current increases rapidly, and the AC voltage distortion is worsened, resulting in system instability. The commutation failure was predicted under this condition by using the conventional commutation area method and the method disclosed in the present disclosure. Prediction results are shown as condition 4 in Table 2, where x denotes a missed prediction by the conventional method, while the method disclosed in the present disclosure successfully predicts the failure at 0.8232 s. A further validation was performed by applying single-phase ground faults with different impedance values on the inverter AC side, where the impedance values ranged from 0.14 H to 0.2 H, including 7 distinct fault impedances with a step size of 0.1 H; and the fault duration was consistently 100 ms. Prediction effects of the two methods are compared, and prediction results are as shown in table 2. In Table 2, the first column lists fault test conditions, the second column lists ground impedance values, the third column lists actual occurrence instant of the commutation failure after the fault, where “not occurred” indicates that no commutation failure occurs during the fault and system recovery period; the fourth and fifth columns present instants at which the commutation failure is judged (the instant when the criterion becomes less than 0) by the conventional commutation area method and the method of the present disclosure respectively; and x denotes a missed prediction for the commutation failure, indicating that the method fails to successfully predict the commutation failure before the actual commutation failure occurs; and denotes no false prediction for the commutation failure, indicating that the criterion remains greater than zero when the system experiences no commutation failure. As can be seen from the data in Table 2, for single-phase fault conditions 1, 2, and 3, both the conventional method and the method of the present disclosure can successfully predict the commutation failure before the actual commutation failure occurs; the method of the present disclosure can predict the commutation failure earlier compared to the conventional method, and has a higher prediction speed; under the single-phase fault condition 4, the missed prediction for the commutation failure occurs in the conventional method, whereas the method of the present disclosure successfully predicts the commutation failure in advance; and for single-phase fault conditions 5, 6, and 7, no commutation failure occurs, both the conventional method and the method of the present disclosure have no false prediction.

TABLE 2
Commutation failure prediction result
under a single-phase fault condition

| | | | Occurrence | | |
|---|---|---|---|---|---|
| | | | instant of the | | |
| Test | Ground | | commutation | Conventional | Disclosed |
| condition | impedance | | failure | method | method |
| Condition | 0.14 | H | 0.8079 s | 0.7930 s | 0.7918 s |
| 1 | | | | | |
| Condition | 0.15 | H | 0.8179 s | 0.8023 s | 0.7935 s |
| 2 | | | | | |
| Condition | 0.16 | H | 0.8179 s | 0.8135 s | 0.8035 s |
| 3 | | | | | |
| Condition | 0.17 | H | 0.8279 s | x | 0.8232 s |
| 4 | | | | | |
| Condition | 0.18 | H | Not occurred | ✓ | ✓ |
| 5 | | | | | |
| Condition | 0.19 | H | Not occurred | ✓ | ✓ |
| 6 | | | | | |
| Condition | 0.2 | H | Not occurred | ✓ | ✓ |

7

Note:
the fourth column lists the instants when the criterion in the conventional method is less than 0; the fifth column lists the criterion in the method of the present disclosure is less than 0; x denotes that the actual commutation failure is not successfully predicted before the occurrence, namely, missed prediction happens; and ✓ denotes that the criterion is consistently greater than 0 when the system has no commutation failure, namely, no false prediction.

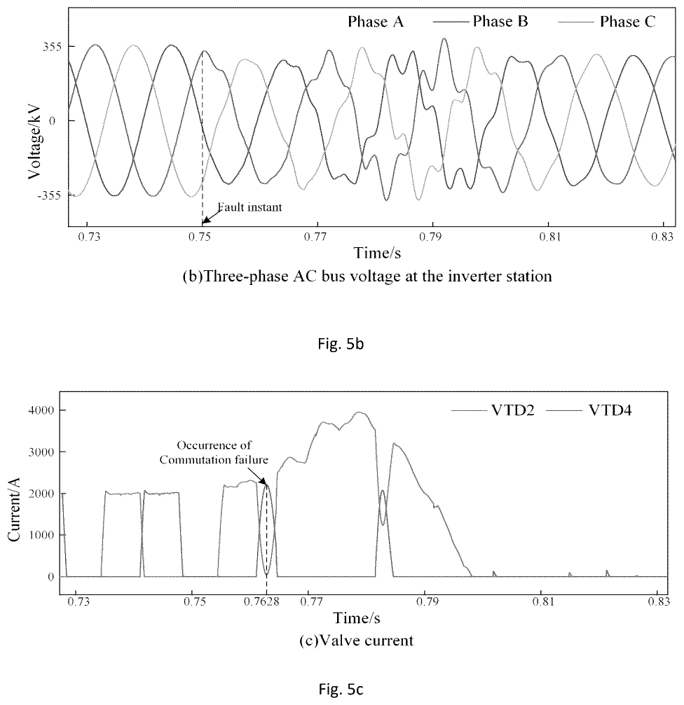

Validation was further performed by taking a three-phase symmetrical ground fault as an example. A three-phase symmetrical ground fault was set at an inverter-side AC bus of the system, and a ground impedance was 0.18H. Relevant waveforms under the condition are shown in FIG. 5; and in FIG. 5, (a) shows the DC current waveform in proximity to a fault instant; (b) shows the three-phase AC bus voltage waveform in proximity to the fault instant; and (c) shows the valve current waveforms of two valves where a first commutation failure occurs. As can be seen from FIG. 5, upon the occurrence of the three-phase ground fault, the DC current exhibits fluctuations, and the AC voltage of the three phases A, B, and C shows a significant drop; and furthermore, the first commutation failure occurs at 0.7628 s during the commutation process of valves 2 to 4 of the converter corresponding to a D1-connected transformer. The commutation failure was predicted under this condition by using the conventional commutation area method and the method disclosed in the present disclosure. Prediction results are shown as the condition 2 in Table 3; and the conventional method achieves successful prediction at 0.7560 s, while the method of the present disclosure achieves the successful prediction at 0.7532 s. The three-phase symmetrical ground fault was further set at an inverter AC bus of the system; the impedance values ranged from 0.13 H to 0.28 H, including 4 distinct fault impedances with a step size of 0.5 H; and the fault duration was consistently 100 ms. The prediction effects of the two methods are shown in Table 3. As can be seen from data in Table 3, under the three-phase fault condition 1, missed prediction of the commutation failure occurs in the conventional method, and the method of the present disclosure predicts the commutation failure in advance; under the three-phase fault condition 2, both the conventional method and the method of the present disclosure successfully predict the commutation failure before the occurrence, and the method of the present disclosure can judge the commutation failure earlier compared to the conventional method; and under the three-phase fault conditions 3 and 4, no commutation failure occurs, both the conventional method and the method of the present disclosure have no false prediction. Thus, it can be seen that the method disclosed in the present disclosure can predict the commutation failure more rapidly on the premise of ensuring the accuracy upon the occurrence of the single-phase ground fault in the LCC-HVDC inverter-side AC system, thereby facilitating the subsequent activation of a commutation failure control and protection system.

TABLE 3
Commutation failure prediction result under
three-phase symmetrical fault conditions

| | | Occurrence | | |
|---|---|---|---|---|
| | | instant of the | | |
| Test | Ground | commutation | Conventional | Disclosed |
| condition | impedance | failure | method | method |
| Condition | 0.13 H | 0.7528 s | x | 0.7525 s |
| 1 | | | | |
| Condition | 0.18 H | 0.7628 s | 0.7560 s | 0.7532 s |
| 2 | | | | |
| Condition | 0.23 H | Not occurred | ✓ | ✓ |
| 3 | | | | |
| Condition | 0.28 H | Not occurred | ✓ | ✓ |
| 4 | | | | |

Note:
the fourth column lists the instants when the criterion in the conventional method is less than 0; the fifth column lists the instants when the criterion in the method of the present disclosure is less than 0; x denotes that the actual commutation failure is not successfully predicted before the occurrence, namely, missed prediction happens; and ✓ denotes that the criterion is consistently greater than 0 when the system has no commutation failure, namely, no false prediction.

What is claimed is:

1. A rapid prediction method for a commutation failure in a high voltage direct current transmission system (HVDC) based on a commutation failure risk factor, comprising: calculating the conventional commutation need area S_{need.t}, the conventional maximum available commutation area S_{pro.t}, and the advanced commutation need area S_{need.c}, the advanced maximum available commutation area S_{pro.c} based on a present-instant commutation voltage magnitude U_{com.t}, a present-instant DC current I_{d.t}, a future-instant commutation voltage magnitude U_{com.c}, and a future-instant DC current I_{d.c}, respectively, then integrating the conventional commutation areas and the advanced commutation areas through adaptive weight coefficients C₁ to C₄, to obtain a commutation failure risk factor F, and further determining whether the commutation failure occurs, thereby achieving rapid prediction for the commutation failure upon the occurrence of a fault in a line-commutated converter-HVDC (LCC-HVDC) system;
comprising the following steps:
step 1: obtaining, in real-time, the present-instant commutation voltage magnitude U_{com.t}, the present-instant DC current I_{d.t}, the future-instant commutation voltage magnitude U_{com.c}, the future-instant DC current I_{d.c}, and a firing angle instruction value a during an operation process of the LCC-HVDC system, wherein all values are per-unit values;
step 2: calculating a required commutation area and an available maximum commutation area based on the present-instant commutation voltage magnitude U_{com.t}, the present-instant DC current I_{d.t}, and the firing angle instruction value α, and defining the calculated required commutation area and the calculated available maximum commutation area as a conventional required commutation area and a conventional available maximum commutation area, respectively; and simultaneously, calculating the required commutation area and the available maximum commutation area based on the predicted future-instant commutation voltage magnitude U_{com.c}, the future-instant DC current I_{d.c}, and the firing angle instruction value α, and defining the calculated required commutation area and the calculated available maximum commutation area as an advanced required commutation area and an advanced available maximum commutation area, respectively;
step 3: calculating weight coefficients of the conventional required commutation area and the advanced required commutation area;
step 4: calculating weight coefficients of the conventional available maximum commutation area and the advanced available maximum commutation area; and
step 5: performing weighted integration on the calculated conventional required commutation area, the calculated conventional available maximum commutation area, the calculated advanced required commutation area, and the calculated advanced available maximum commutation area through the weight coefficients, to obtain the commutation failure risk factor, and then predicting whether the commutation failure occurs; and during a prediction process, adaptively adjusting the weight coefficients of the commutation areas based on prediction errors of characteristic quantities at a previous instant;
in step 5, based on the conventional commutation need area S_{need.t}, the conventional maximum available commutation area S_{pro.t}, the advanced commutation need area S_{need.c}, the advanced maximum available commutation area S_{pro.c}, and the weight coefficients C₁ to C₄ calculated in step 2 to step 4, calculating the commutation failure risk factor F in real time according to Formula (8);
$$F = {C}_{1} {S}_{n e e d . c} + {C}_{2} {S}_{n eed . t} + {C}_{3} {S}_{pro . c} + {C}_{4} {S}_{pro . t} \qquad ( 8 )$$
wherein if F≥0, a system state satisfies a normal commutation condition, and the commutation failure will not occur; and if F<0,the system state does not satisfy the normal commutation condition, and the commutation failure will occur.

2. The rapid prediction method for a commutation failure in an HVDC based on a commutation failure risk factor according to claim 1, wherein in step 2, based on the present-instant commutation voltage magnitude U_{com.t}, the present-instant DC current I_{d.t}, and the firing angle instruction value α, calculating the conventional required commutation area S_{need.t} and the conventional available maximum commutation area S_{pro.t} according to Formula (2) and Formula (3), respectively; and
based on the predicted future-instant commutation voltage magnitude U_{com.c}, the future-instant DC current I_{d.c}, and the firing angle instruction value a, calculating the advanced required commutation area S_{need.c} and the advanced available maximum commutation area S_{pro.c} according to Formula (4) and Formula (5), respectively;
$${S}_{n eed . t} = 2 {X}_{c} {I}_{d . t} \qquad ( 2 )$$
$${S}_{pro . t} = {\int }_{α}^{π - {γ}_{min}} {U}_{com . t} sin ( {ω}_{0} t ) d ( {ω}_{0} t ) \qquad ( 3 )$$
$${S}_{need . c} = 2 {X}_{c} {I}_{d . c} \qquad ( 4 )$$
$${S}_{pro . c} = {\int }_{α}^{π - {γ}_{min}} {U}_{com . c} sin ( {ω}_{0} t ) d ( {ω}_{0} t ) \qquad ( 5 )$$
Wherein X_{c} denotes the equivalent commutation reactance; γₘᵢₙ denotes a minimum extinction angle; ω₀ denotes a system angular frequency, with a value of 2π/T, wherein T denotes a fundamental period of the system; and t denotes an integral variable.

3. The rapid prediction method for a commutation failure in an HVDC based on a commutation failure risk factor according to claim 1, wherein in step 3, based on the present-instant DC current I_{d.t} and a predicted value I_{d.c0} of the present-instant DC current in historical data, calculating the weight coefficients C₁ and C₂ of the conventional required commutation area and the advanced required commutation area according to Formula (6);
$$\{ \begin{matrix}{C}_{1} = - \frac{{k}_{i 1} {e}^{{k}_{i 2} \vert {I}_{d . t} {I}_{d . c 0} \vert}}{1 + {e}^{{k}_{i 2} \vert {I}_{d . t} - {I}_{d . c 0} \vert}} \\ {C}_{2} = - 1 - {C}_{1}\end{matrix} \qquad ( 6 )$$
Wherein kᵢ₁ denotes a normalization coefficient of required commutation area weights, and kᵢ₂ denotes a sensitivity coefficient of the required commutation area weights.

4. The rapid prediction method for a commutation failure in an HVDC based on a commutation failure risk factor according to claim 1, wherein in step 4, based on the present-instant commutation voltage magnitude U_{com.t} and a predicted value U_{com.c0} of the present-instant commutation voltage magnitude in the historical data, calculating the weight coefficients C₃ and C₄ of the conventional available maximum commutation area and the advanced available maximum commutation area according to Formula (7);
$$\{ \begin{matrix}{C}_{3} = \frac{{k}_{u 1} {e}^{{k}_{u 2} \vert {U}_{com . t} - {U}_{com . c 0} \vert}}{1 + {e}^{{k}_{u 2} \vert {U}_{com . t} - {U}_{com . c 0} \vert}} \\ {C}_{4} = 1 - {C}_{3}\end{matrix} \qquad ( 7 )$$
Wherein kᵤ₁ denotes a normalization coefficient of available maximum commutation area weights, and kᵤ₂ denotes a sensitivity coefficient of the available maximum commutation area weights.

5. A computer readable storage medium, having programs stored therein, the programs, when executed by a processor, performing the steps in the rapid prediction method for a commutation failure in an HVDC based on a commutation failure risk factor according to claim 1.

6. An electronic device, comprising a memory, a processor, and programs stored in the memory and capable of running on the processor, the processor, when executing the programs, performing the steps in the rapid prediction method for a commutation failure in an HVDC based on a commutation failure risk factor according to claim 1.
